(19) United States
(12) Patent Application Publication
(10) Pub. No.: US 2011/0221018 A1
(43) Pub. Date: Sep. 15, 2011

(54) Electronic Device Package and Methods of Manufacturing an Electronic Device Package

(76) Inventors: Xunqing Shi, Hong Kong (HK); Dan Yang, Hong Kong (HK); Pui Chung Simon Law, Hong Kong (HK)

(21) Appl. No.: 12/723,992

(22) Filed: Mar. 15, 2010

(51) Int. Cl. H01L 31/0232; H01L 31/02; H01L 31/18

(52) U.S. Cl. 257/432; 257/459; 438/69; 257/E31.127; 257/E31.113

(57) ABSTRACT

An electronic device package comprises a substrate 110 having a first surface 110a and a second surface 110b opposite the first surface. An electronic device 120, 130 is positioned on the first surface 110a. An isolation layer 140 extends over at least a portion of the top surface of the electronic device. A redistribution layer 145 having one or more I/O lines extends over the isolation layer and the top surface of the electronic device. The RDL layer connects the electronic device to one or more first vias 160 which pass through the substrate 110 to the second surface 110b thereof. The electronic device may be an image sensor. A microlens 220 and protective parylene layer 230 may be fabricated over the image sensor. A method of manufacturing the electronic device package is also disclosed.

The present invention relates to an electronic device package and a method of manufacturing the electronic device package. The electronic device package preferably comprises an integrated circuit; it may for example comprise an image sensor or a MEMS device.

### BACKGROUND TO THE INVENTION

FIG. 1 shows a conventional CMOS image sensor (CIS) package. The package comprises a ceramic substrate 2 and an integrated circuit (IC) 3 mounted on the substrate. An adhesive layer 4 is provided between the IC 3 and the substrate 2. Bonding pads 6 are provided on an upper surface of the IC 3 and connected to bonding pads 8 on an upper surface of the substrate by wires 7. An optically interactive element 5, such as a photodiode, is provided on top of the IC 3. The arrangement is enclosed in a frame 10, which has a lens 9 for focusing light on the optically interactive element 5.

FIG. 2 shows an improved prior art CIS package which uses microlenses and a glass cover. It is sometimes called a TSV arrangement (through-silicon-via) because it has a via which extends through a silicon substrate. As shown in FIG. 2 there is a silicon substrate 23 and an integrated circuit (IC) 21 is positioned on a top surface of the substrate 23. A plurality of microlenses 22 are fabricated over an optically interactive area of the IC 21. Side edges of the IC 21 connect I/Os of the IC to a redistribution layer (RDL) 25. The re-distribution layer connects the IC to through-silicon-vias (TSV) 26. The TSVs 26 extend from a top surface of the substrate to a bottom surface of the substrate where they connect to bonding pads 27. The bonding pads 27 are connected to solder balls 28. A polymer spacer 24 is provided over the substrate 23 and a portion of the redistribution layer 25. The polymer spacer 24 supports a thick glass cover 29 which forms a top part of the device package.

The CIS package shown in FIG. 2 has several advantages over FIG. 1. Notably it can be made smaller as it uses microlenses rather than a bulky glass lens. In addition, the use of a RDL, instead of wire bonding, reduces the size further. Furthermore, the FIG. 2 arrangement can be conveniently manufactured by wafer level processing and surface mount technology which reduces costs.

FIGS. 3 (a) to (h) show a method of manufacturing the CIS package of FIG. 2. In the first step, shown in FIG. 3(a), a polymer spacer 24 is attached to a glass wafer 29. The spacer 24 has a large central aperture for allowing passage of light and accommodating the microlenses, which are added later.

FIG. 3(b) shows a second step in which a silicon substrate 23, having an IC 21 on its top surface, is provided. Microlenses 22 are fabricated over an optically interactive area of the IC 21. A conductive redistribution layer 25 is fabricated on a part of the top surface of the substrate 23 and connected to side edges of the IC 21. The glass wafer 29 and spacer 24 are adhered to the top of the substrate 23.

In a third step, shown in FIG. 3(c), the silicon substrate 23 is thinned by use of a grinding machine, or by other means. The wafer is thinned to 75 μm or less in order to keep the device small and to compensate for the relatively thick glass wafer 29. This thinning of the substrate 23 is possible because while the silicon substrate might snap if it was unsupported, it can be made thin when it supported by the glass wafer 29.

In a fourth step, shown in FIG. 3(d), via holes 26a are formed in the substrate by using a dry etching process such as DRIE. The via holes 26a are formed from the bottom surface of the substrate upwards (the top surface is the surface to which the glass wafer is mounted, the bottom surface is the surface facing away from the glass wafer). Formation of the via holes 26a is the first stage in forming the TSVs 26.

In a fifth step, shown in FIG. 3 (e), a PECVD isolation layer 26b is added to the interior of the via holes 26a.

In a sixth step, shown in FIG. 3(f), a barrier or seed layer 26c is added to the interior of the via holes 26a, by sputtering.

In a seventh step, shown in FIG. 3(g), the via holes 26a are filled with a conductive metal material 26d by electroplating.

In an eighth step, shown in FIG. 3(h), bonding pads 27 are connected to the bottom end of the vias 26. These bonding pads 27 contact the conductive metal 26d which forms the core of the vias 26. Solder balls 28 are then formed on the bonding pads 27.

The CIS package of FIG. 2 and the manufacturing method of FIG. 3 have certain disadvantages. Firstly, the glass layer 29 is expensive, heavy and takes up a lot of space. In addition, as the glass layer 29 is a completely different material compared to the silicon substrate 23 and has a different stiffness, it can become chipped during the manufacturing process. This often happens when the substrate wafer is cut into several pieces to separate a plurality of devices formed on the substrate. In addition, the glass layer has to be thick because it is used to support the substrate wafer during the manufacturing process. In order to compensate for the thick glass layer, the silicon substrate layer is made thinner than would otherwise be the case, e.g. less than 75 μm. This can lead to micro-cracks in the substrate layer as it is so thin.

In addition the TSVs 26 are formed by a dry etching process such as reactive ion etching. As the silicon substrate wafer 23 will often bend slightly inwards or outwards towards its centre, the length of a TSV must be greater if it is near the edge of the wafer than if is near the centre of the wafer. As the same amount of gas is used to etch each via, the vias near the centre of the wafer tend to be over-etched. As the gas cannot etch the metal RDL layer above the silicon wafer, any excess gas at the top part of the via tends to spread outwards increasing its diameter larger than is necessary. Furthermore the via has a SiO₂ isolation layer and a Ti/W bonding or adhesion layer with an electroplated Cu layer in the centre. Electroplating the Cu layer is an expensive process.

### SUMMARY OF THE INVENTION

A first aspect of the present invention provides an electronic device package comprising a substrate having a first surface and a second surface opposite the first surface; an electronic device being positioned on the first surface of the substrate; an isolation layer provided over a at least at least a portion of a top surface of the electronic device; one or more I/O lines connected to the electronic device and extending over the isolation layer and the top surface of the electronic device, and one or more first vias which pass through the substrate and connect said one or more I/O lines to the second surface of the substrate.

The isolation layer is preferably over peripheral regions of the electronic device. The active regions, usually the central regions, which may e.g. comprise an optically interactive component are preferably not covered by the isolating layer. In other cases the active region which is not covered may be in a non-central or even a peripheral region of the electronic device. If the electronic device is a MEMS device then usually, although not necessarily, substantially the entire top surface of the device will be covered with the insulating layer.

While in the above example there is an isolation layer between the I/O lines and the top surface of the electronic device, in order to prevent the I/O lines from shorting out, there may optionally be further additional layers between the I/O lines and the top surface of the electronic device.

Preferably at least some of said I/O lines extend from one side of the electronic device (i.e. peripheral region near a side edge) over the top surface of the electronic device to another side of the electronic device. Preferably the I/O lines connect the electronic device to one or more first vias on no more than two sides of the substrate (i.e. the first vias are adjacent no more than two sides of the electronic device); more preferably on just one side of the electronic device.

The electronic device may comprise an integrated circuit (IC). The electronic device may be an image sensor. The image sensor may comprise an optically interactive component and an IC for driving the optically interactive component. The electronic device may be a MEMS device; the MEMS device may comprise a MEMS chip and a driver chip (e.g. IC) for driving the MEMS chip.

The electronic device may comprise an optically interactive device. A microlens may be positioned over the optically interactive device.

Preferably the I/O lines are connected to the electronic device by one or more second vias which extend through said isolation layer (to the top surface of the electronic device). Alternatively the I/O lines may be connected to the sides of the electronic device (e.g. by passing over the top edge past the isolation layer and to the side of the electronic device).

A second aspect of the present invention provides an optically interactive device package comprising an optically sensitive area and a microlens positioned over the optically sensitive area; the microlens being coated with a protective polymer layer.

The protective polymer layer preferably comprises parylene. The protective polymer layer is preferably from 0.05 μm to 5 μm.

The optically interactive device may be an image sensor, e.g. a CIS.

The first and second aspects of the present invention may be combined together.

A third aspect of the present invention provides a method of manufacturing an electronic device package comprising:—
a) providing an electronic device on a substrate;
b) providing an isolation layer over at least a portion of a top surface of said electronic device;
c) forming one or more first vias extending through said substrate; and
d) forming one or more I/O lines extending over the isolation layer and the top surface of the electronic device;
said I/O lines connecting the electronic device to the at least one first via.

Steps c) and d) may be performed in either order (e.g. step c first or step d first).

Preferably the substrate has a first surface and a second surface and the electronic device is provided on a first surface of the substrate and wherein the one or more first vias are formed by drilling or etching from the first surface towards the second surface of the substrate.

The electronic device may be an optically interactive device. The method may comprise the further step of placing a microlens over the optically interactive device after step c). It may be performed between steps c) and d). More preferably the microlens is placed after both steps c) and d).

The optically interactive device may comprise an IC and an optically interactive component. The one or more first vias are preferably connected to the IC by the one or more I/O lines.

The third aspect of the invention may be used to produce an apparatus according to the first or second aspects of the present invention.

A fourth aspect of the present invention provides a method of making an optically interactive device package comprising the steps of providing an optically interactive device on a substrate and forming a protective polymer film over an optically sensitive area of the optically interactive device. The fourth aspect of the invention may be used to produce an apparatus according to the second aspect of the invention.

A fifth aspect of the present invention provides an electronic device package comprising a substrate having a first surface and a second surface opposite the first surface; an IC being positioned on the first surface of the substrate; said IC having a bottom surface facing the first surface of the substrate and a top surface facing away from the first surface of the substrate; and a plurality of I/O lines connected to the IC and extending over said top surface of the IC to one or more first vias which pass through the substrate and connect said I/O lines to said second surface of the substrate.

Preferably there is an isolation layer between the plurality of I/O lines and the top surface of the IC. The IC may be connected to said I/O lines by one or more second vias passing through said isolation layer. Preferably the plurality of I/O lines are in a redistribution layer formed over the isolation layer.

A sixth aspect of the present invention provides an electronic device package comprising a substrate having a first surface and a second surface opposite the first surface; an IC being positioned on the first surface of the substrate and a plurality of I/O lines which connect the IC to one or more first vias which pass through the substrate; and wherein the I/O lines connect the IC to first vias on no more than two sides of the IC; more preferably on just one side of the IC.

The one or more first vias connect said I/O lines to said second surface of the substrate

The fifth and sixth aspects of the present invention may have any of the features of the first and second aspects of the present invention. A seventh aspect of the present invention is a method of making the apparatus according to the fifth and sixth aspects of the present invention.

### BRIEF DESCRIPTION OF THE DRAWINGS

Embodiments of the present invention will now be described in detail, by way of example only, with reference to the accompanying drawings in which:

FIG. 1 is a schematic view of a prior art CIS which has already been described;

FIG. 2 is a schematic view of another prior art CIS which has already been described;

FIGS. 3(a) to (h) show a method of manufacturing the CIS of FIG. 2 and have already been described;

FIG. 4 is a schematic view of an electronic device package according to an embodiment of the present invention;

FIG. 5 is a detailed schematic view of an optically interactive electronic device package according to a preferred embodiment of the present invention;

FIG. 6 is a top down view of a conventional IC and surrounding I/Os and substrate;

FIG. 7 is a top down view of an IC and surrounding I/Os and substrate in a package according to an embodiment of the present invention;

FIG. 8 is a top down view of an IC and surrounding I/Os and substrate in a package according to another embodiment of the present invention;

FIG. 9 is a schematic view of a portion of the electronic device package of FIG. 5; in particular it illustrates light incident on the microlenses and IC;

FIGS. 10 (a) to (c) illustrate various arrangements of microlenses;

FIG. 11 (a) is a cross sectional view along the line I-I of FIG. 7 and illustrates the redistribution layer, a first via and the second vias;

FIG. 11 (b) is a cross sectional view along the line A-A of FIG. 11 (a) and illustrates the arrangement of the second vias;

FIG. 11 (c) is a cross sectional view along the line B-B of FIG. 11 (a) and illustrates the first vias;

FIG. 12 is a cut away top down view of the device package showing how the redistribution layer connects with the first and second vias;

FIG. 13 (a) is a flow diagram of a conventional order of manufacturing an image sensor package;

FIG. 13 (b) is a flow diagram of a new method of manufacturing an image sensor package in which the order of steps is changed; and

FIGS. 14 (a) to 14 (l) illustrate steps in manufacturing the package of FIG. 5.

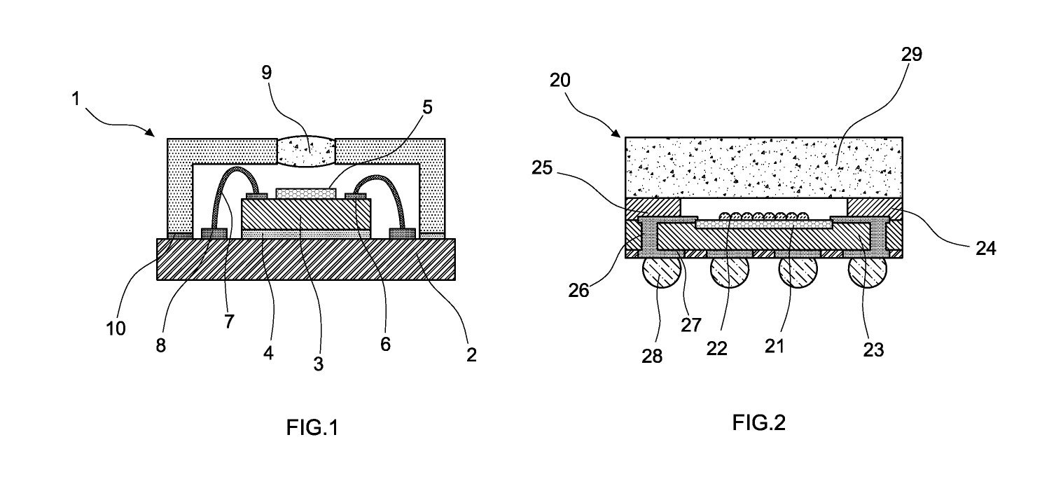

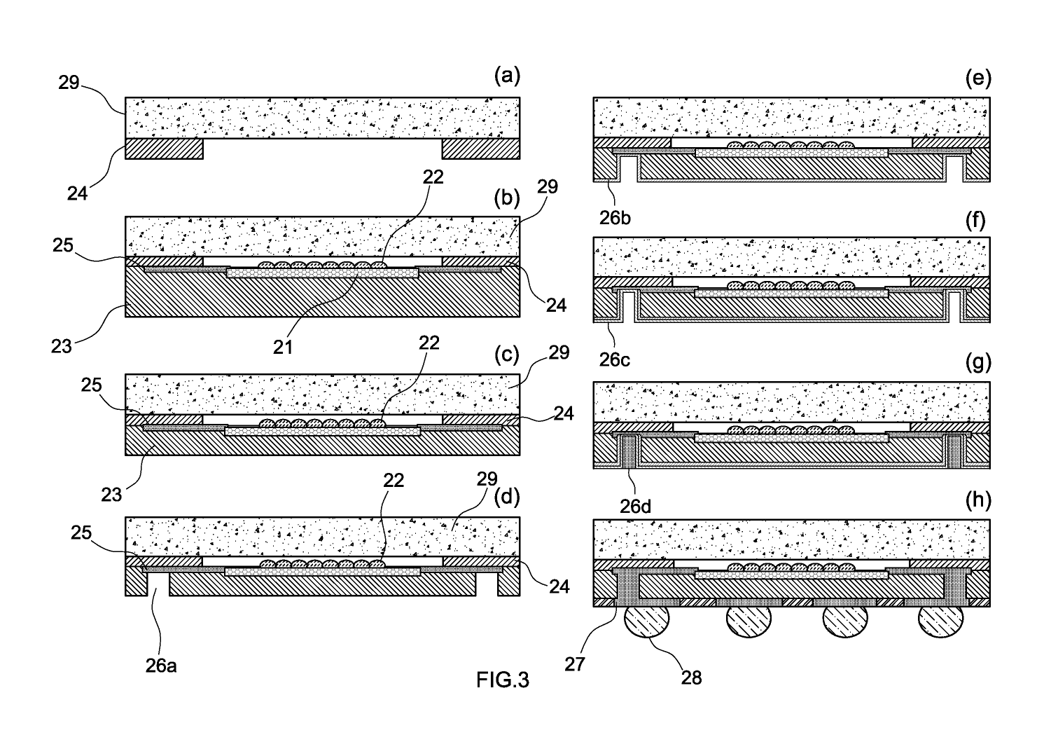

### DETAILED DESCRIPTION

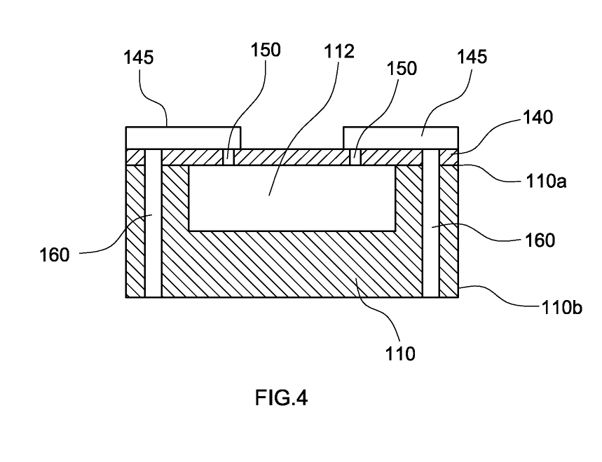

FIG. 4 is a schematic view of an electronic device package according to an embodiment of the present invention. The package comprises an electronic device 112 and a substrate 110. The substrate preferably comprises silicon. The substrate has an upper or first surface 110a and a lower or second surface 110b. A redistribution layer 145 comprises conductive I/O lines which extend over the top surface of the electronic device 112. The I/O lines connect I/Os of the electronic device to first vias 160. First vias 160 extend through the substrate 110 from its first surface 110a to its second surface 110b. In the illustrated arrangement an isolation layer 140 is provided over the electronic device 112 and the first surface of the substrate 110. The redistribution layer 145 connects to the electronic device 112 by second vias 150 which extend through the isolation layer 140.

The electronic device may be an image sensor, e.g. a CMOS Image Sensor (CIS). Preferably it comprises an integrated circuit (IC). The electronic device does not have to be an image sensor however as the above packaging method may be applied to many different types of electronic device and not just image sensors. In other embodiments the electronic device may, for example, be a MEMS device.

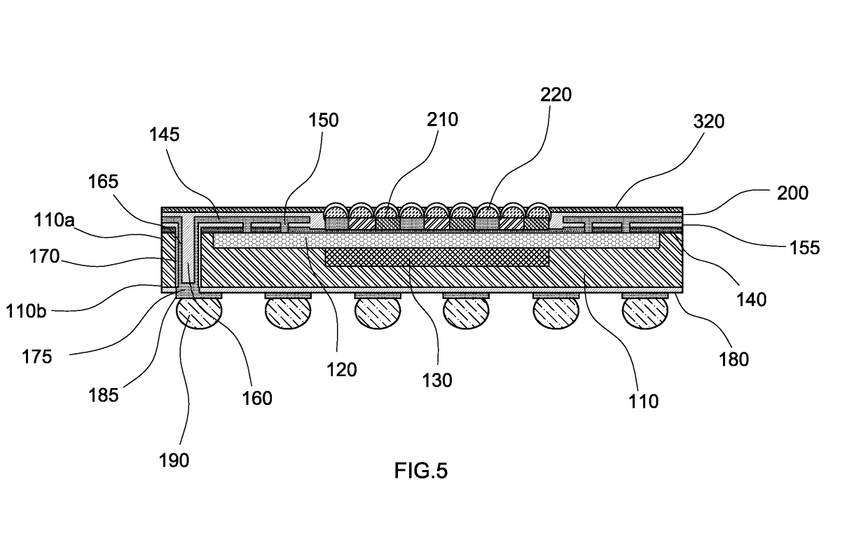

A preferred embodiment will now be described in more detail with reference to FIG. 5. The package comprises an optically interactive electronic device and a substrate 110. The substrate preferably comprises silicon. The substrate has an upper or first surface 110a and a lower or second surface 110b. An IC 120 is placed on an upper surface of the substrate 110. An optically interactive component 130, such as one or more photodiodes, is placed between a lower surface of the IC 120 and an upper surface of the substrate 110. Preferably the optically interactive component is below a central portion of the IC. A portion of the IC may be transparent to light so that light can pass through to the optically interactive component below. Together the IC 120 and the optically interactive component 130 form an optically interactive device such as a CIS (CMOS Image Sensor).

An isolation layer 140 and a (optional) dielectric layer 155 are fabricated over peripheral portions of the upper surface of the IC 120. The central region of the IC 120 is preferably not covered by the dielectric and isolation layers so that light may pass through to the optical component below. In alternative embodiments a peripheral region of the device is not covered by the insulating and dielectric layers and the optical component may be below said peripheral uncovered area (while the central region may be covered). Alternatively, the entire surface may be covered if the isolating layer (and/or dielectric layer) is of a material which allows passage of light or if the electronic device is a non-optical (e.g. MEMS) device.

Returning to FIG. 5, I/O points on the top surface of the IC 120 are connected to a redistribution layer (RDL) 145. The redistribution layer 145 lies over the (optional) dielectric layer 155, the isolation layer 140 and the upper surface of the IC 120. The redistribution layer 145 is connected to the I/Os (I/O points) of the IC 120 by one or more second vias 150. The second vias 150 may alternatively be called ‘vertical vias’ as usually they extend vertically between the redistribution layer and the IC.

The redistribution layer 145 comprises a plurality of conductive I/O lines which are connected to the I/Os of the IC. The I/O lines extend over the upper surface of the IC and connect to one or more first vias 160. The one or more first vias 160 extend through the substrate 110 from the first surface 110a to the second surface 110b.

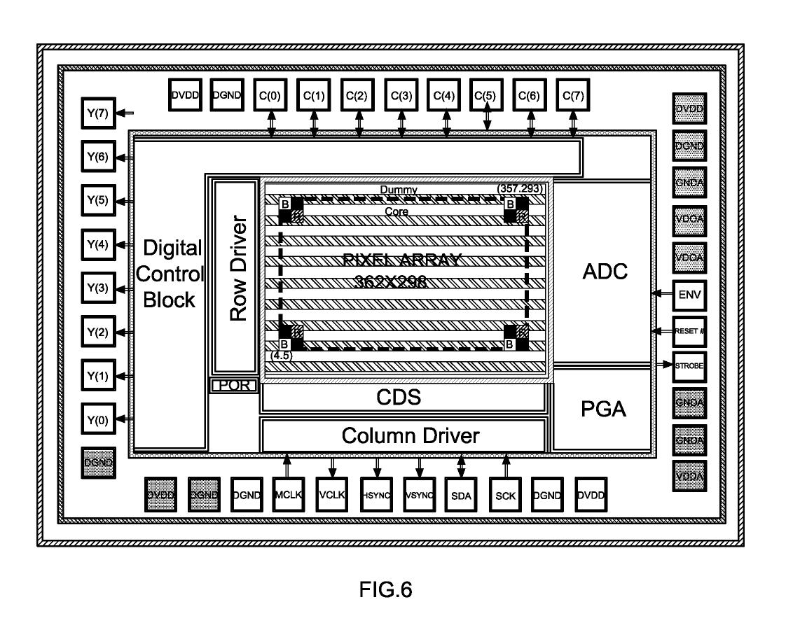

FIG. 6 shows a conventional arrangement in which the I/Os of the IC are at the side edges of the IC. In this conventional arrangement the I/Os are on all four sides of the IC. Typically the IC has several different blocks, for example a Digital Control Block, a Column Driver, an Analogue-to-Digital Converter (ADC), a Correlated Double Sampling (CDS), and a Programming Gain Amplifier (PGA). Other types of block will be apparent to a person skilled in the art. In the conventional design the I/Os for each respective block are adjacent the side of the IC which the block is located on. So, for example, the ADC I/Os are located on the right side in FIG. 6.

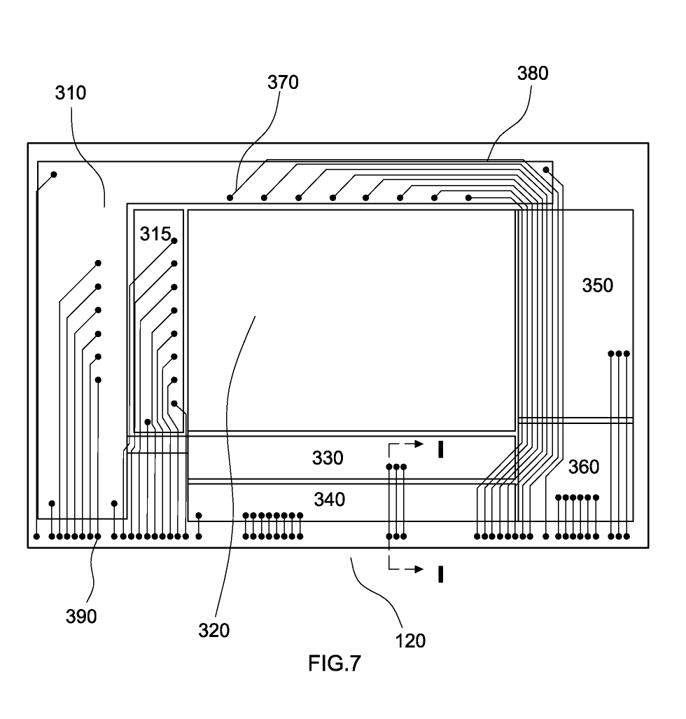

FIG. 7 shows an arrangement according to the present invention in which all the I/Os are routed to one side of the substrate (or more specifically to first vias adjacent one side of the IC). This is made possible because the I/O points 370 are on the top surface of the IC (the surface facing away from the substrate 110). I/O lines 380 extend over the top surface of the IC and connect the I/O points 370 to points 390 along a first side of the IC. The IC has a plurality of different blocks 310, 315, 330, 340, 350 and 360. It can be seen that I/Os from all of these blocks are routed to one side of the IC. Some of the I/O lines, such as those extending from area 340, are relatively short, while others, such as those extending from area 310, are relatively long and extend from one side of the IC to the other. As the I/Os are routed to only one side of the IC a lot of space is saved and the substrate (e.g. silicon wafer) is not needed on the other three sides to accommodate the I/Os. This minimizes the size of the package and reduces cost as less substrate area is needed.

Block 320 is a pixel area located away from the edges of the IC and preferably in the centre. It is an optically sensitive area and responds to light passing through the IC. Preferably this area is at least partially transparent and light passes through it to an optically interactive component (e.g. photodiodes) below. It is preferred that the I/O lines circumnavigate this area and do not extend over it.

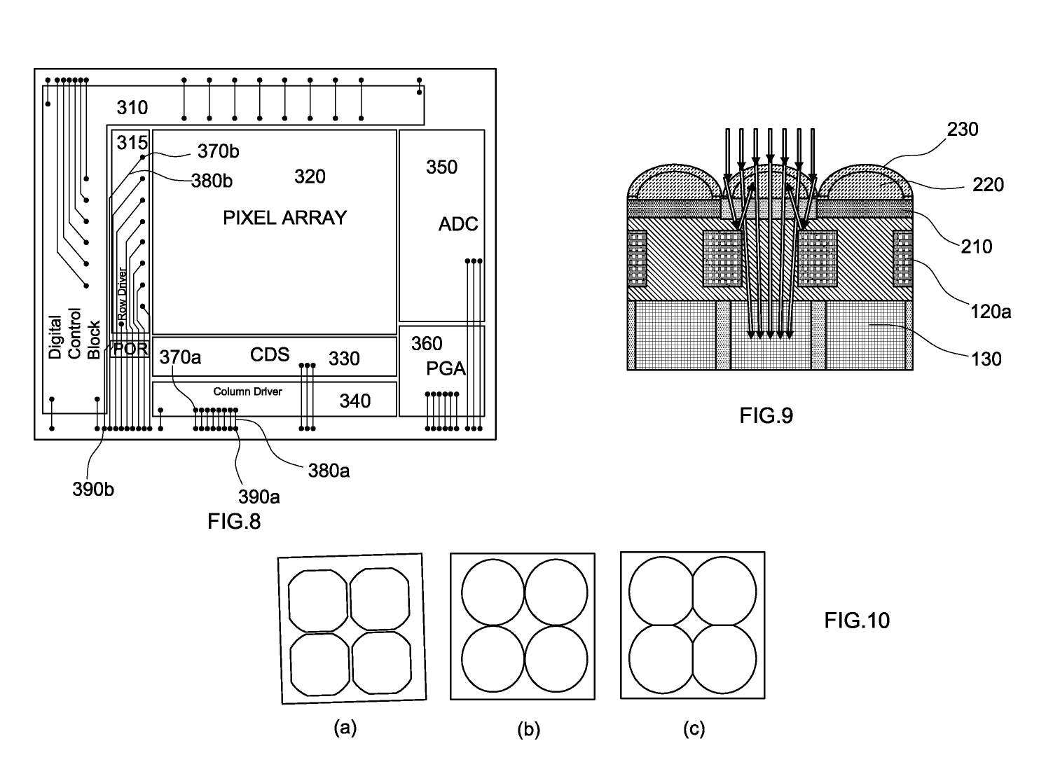

FIG. 8 shows an alternative arrangement in which the I/Os are routed to two sides of the IC. While the space saving is not as great as in FIG. 7, it is still significant. In another arrangement the I/Os could be routed to three sides, although in this case the space saving would not be as great.

Routing the I/Os lines over the top surface of the IC can be thought of as an ‘over the roof’ approach, as the I/O lines are routed over the top or ‘roof’ of the IC. It is a very flexible solution as it makes use of the large amount of available space over the top of the IC. As space is available the I/O lines can be made relatively thick, e.g. up to 50 μm or even more, and therefore can carry a relatively high bandwidth of data. The side or sides to which the I/O lines are routed can be chosen so as to maximize data speed for the most time sensitive or important data. So, for example, if block 340 (which may be a column driver) is particularly important then the I/O lines 380a can be routed to the side adjacent block 340. The I/Os lines 380b from block 315, which may be less important, are longer in length and therefore it takes a longer time for the I/O signals from this block to traverse the IC to points 390b at the side of the IC.

Referring again to FIG. 5, a colour filter 210 is optionally provided over the IC 210 and isolation layer 140. The colour filter overlies the optically interactive component 130. A plurality of microlenses 220 is fabricated over the (optional) colour filter 210 and overlies the optically interactive component 130. The microlenses 220 act to focus light on the optically interactive component 130.

A dielectric layer 200 (e.g. a polymer layer) extends over the RDL layer 145 and up to the colour filter 210. A protective polymer film 230, preferably comprising parylene, extends over the dielectric layer 200 and over the microlenses 220. The protective polymer 230 film helps to protect the microlenses from dust and to keep them clean. The protective polymer layer preferably has low absorption of water.

FIG. 9 is a schematic diagram showing light incident on a portion of the electronic device package. The same reference numerals are used to denote the same parts as in FIG. 5 and will not be described again. The light is refracted by the polymer cover layer 230 and microlense 220. Having been refracted, the light passes through a transparent portion of the IC until it reaches the optically interactive component 130. The optically interactive component 130 may comprise a plurality of photodiodes. The use of microlenses enables the light to be focused through the transparent portions of the IC 120 and thus mimizes back reflection of light. This is a big advantage compared to using a conventional lens. Non-transparent portions 120a of the IC 120, may reflect light, however this is kept to a minimum by suitable spacing of the non-transparent portions.

The microlenses may grouped together in an array. Several possible formations, for four microlenses, are shown in FIGS. 10 (a) to (c). A person skilled in the art will understand how to expand these arrangements to larger arrays.

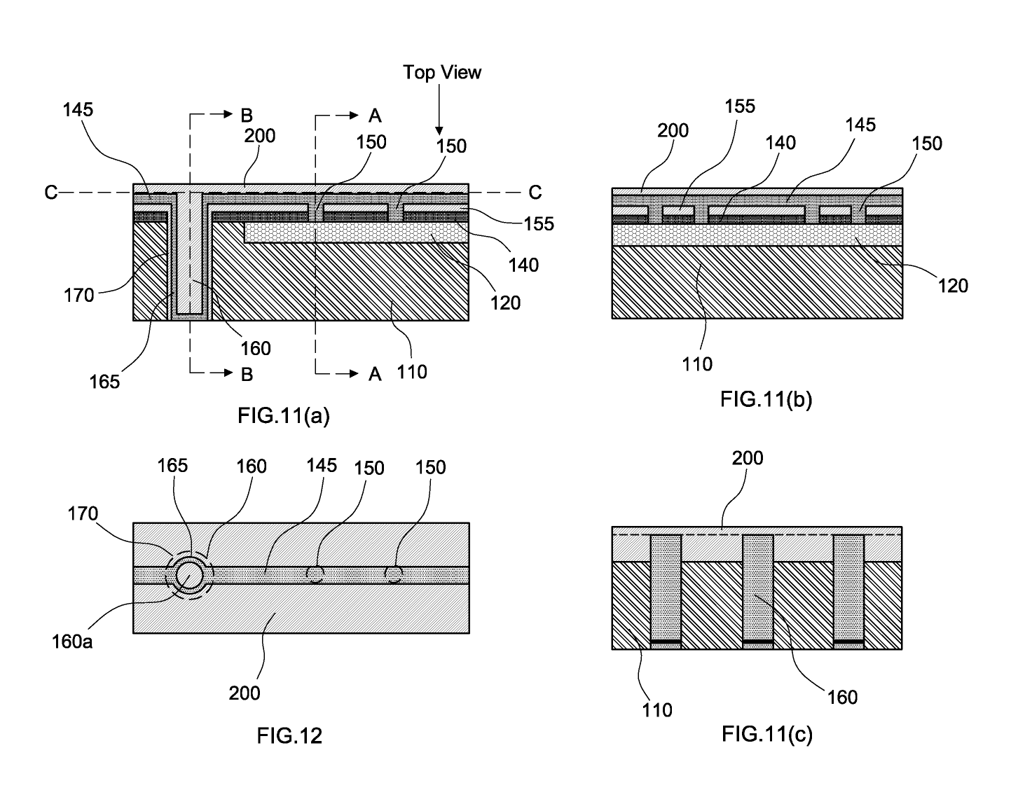

The first and second vias and connections between the redistribution layer, IC and second side of the substrate will now be described with reference to FIGS. 7, 11 (a)-(c) and 12. FIG. 11 (a) is a cross-section of the line I-I in FIG. 7. The redistribution layer (RDL) 145 contains conductive I/O lines that connect the IC 120 to the first vias 160 which extend through the substrate 110.

The RDL 145 connects to I/Os on the top surface of the IC 120 by way of second vias 150. The second vias 150 extend through an isolation layer 140 and optional dielectric layer 155 which lie between the RDL 145 and the IC 120. In an alternative embodiment the redistribution layer 145 may connect directly to the IC 120 by connecting lines which traverse the side edges of the IC rather than second vias which extend through isolation layer 140. The RDL 145 connects to the first via 160. In the illustrated embodiment the RDL 145 connects to a metal liner 165 of the first via 160. An isolation layer 170 is provided on the exterior of the metal liner 165 to insulate it from the rest of the substrate 110. The interior of the first via 160, inward of the metal liner 165, is filled with a dielectric material (e.g. polymer filler).

FIG. 11(b) describes a cross-section of the line A-A in FIG. 11(a). The redistribution layer 145 contains conductive I/O lines that connect to I/Os on the top surface of the IC 120 by way of second vias 150. The second vias 150 extend through an isolation layer 140 and an optional dielectric layer 155, both of which lie between the RDL and the IC.

FIG. 11(c) gives a cross section along the line B-B of FIG. 11(a). The I/O lines of redistribution layer 145 directly connect to the first vias 160 which extend through the substrate 110. Please note the polymer filler 160 is not shown in FIG. 11 (c) so that the first vias 160 can be seen more clearly. Thus while the first vias are shown as solid lines in FIG. 11 (c), in the preferred arrangement each first via actually comprise an isolation layer 170, metal liner 165 and dielectric filler (e.g. polymer). Electrical signals are conducted through the first via by the metal liner 165. This structure internal structure of the first via is an example only; other possible structures would be apparent to a person skilled in the art.

FIG. 12 gives a top-down view of the arrangement (in the direction shown by the arrow in FIG. 11 (a)). Please note that in order that the structure can be shown clearly, the view is as if the dielectric layer (e.g. polymer) 200 on the upper surface has been removed along the dash line C-C shown in FIG. 11(a); i.e. the view is from the dashed line C-C downwards. The configuration of the interconnection, between the first via 160 and second vias 150, provided by the RDL 145 is clearly shown. The first via 160 comprises a via hole 160a which is filled with a dielectric (e.g. a polymer); the dielectric filler is surrounded by a metal liner 165. In turn, the metal liner 165 is surrounded by an isolation layer 170. A connecting line of the RDL 145 extends between the metal liner 165 of the first via and connects it to the second vias 150. The connecting line of the RDL is surrounded by a dielectric (e.g. polymer).

The arrangement shown in FIGS. 11 (a) to 11 (c) and FIG. 12 is an example only. Other possible configurations and constructions of the RDL, first and second vias will be apparent to a person skilled in the art.

Referring back to FIG. 5 the first vias 160 extend through the substrate 110 to the second surface 110b of the substrate 110. Conductive bonding pads 185 are formed to the bottom end of the first vias and to the second surface of the substrate. Solder joints 190 are then formed on the bonding pads 185.

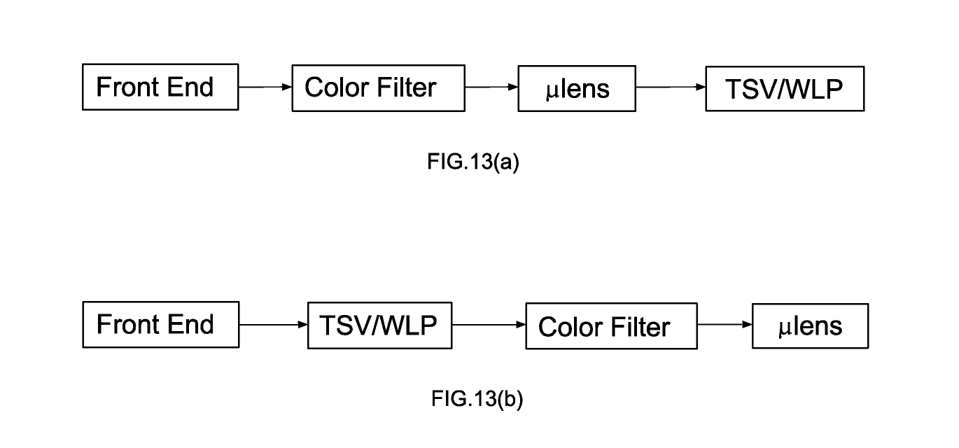

FIG. 13 (a) is a flow chart showing the order of manufacturing steps for a conventional CIS as shown in FIG. 2. FIG. 13(b) is a flow chart showing a preferred order of manufacturing steps for an electronic device package according to a preferred embodiment of the present invention. In FIG. 13 (a) the “front end” or substrate and IC is provided, a colour filter is fabricated on top, followed by a microlens and then the first vias are formed through the substrate 110 (which preferably is a silicon substrate). In FIG. 13 (b) the order is changed so that the first vias are formed after the front end is provided and before addition of the colour filter and/or microlens. The colour filter is optional; it will be used in most, but not all, cases where the device is an image sensor. The main point is that in FIG. 13 (b) the first vias are formed before addition of the microlens and not after.

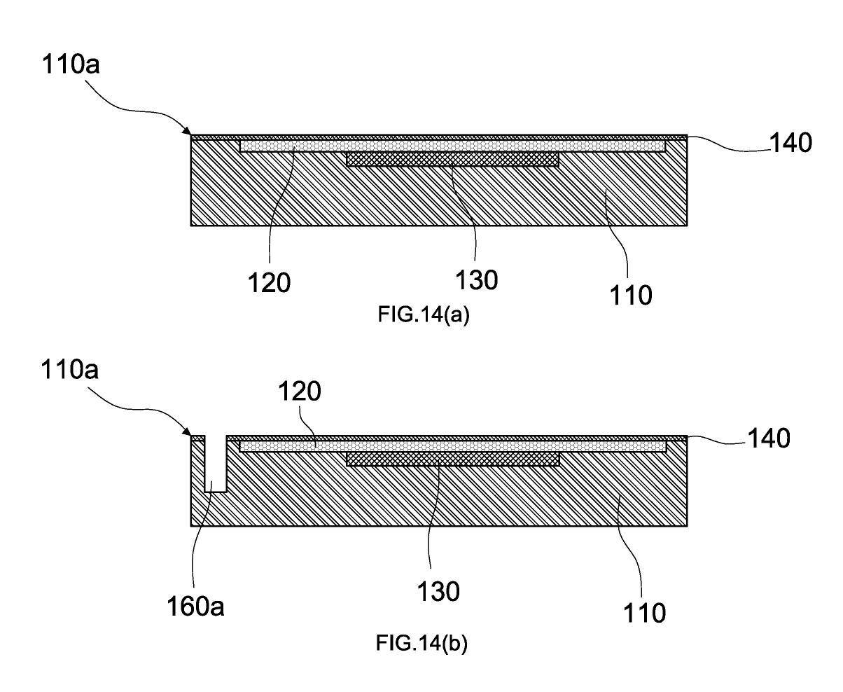

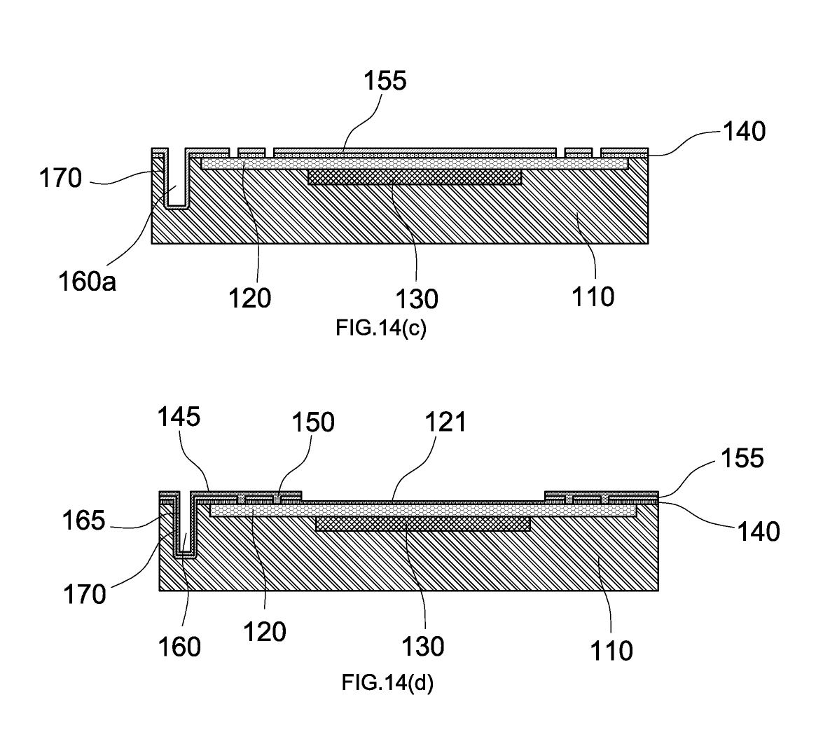

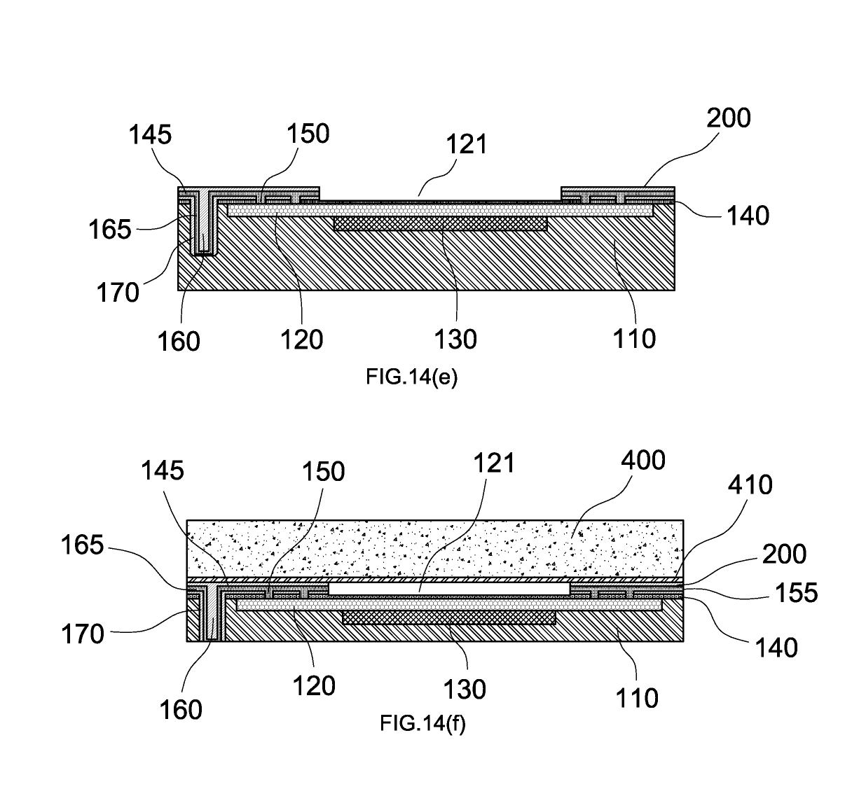

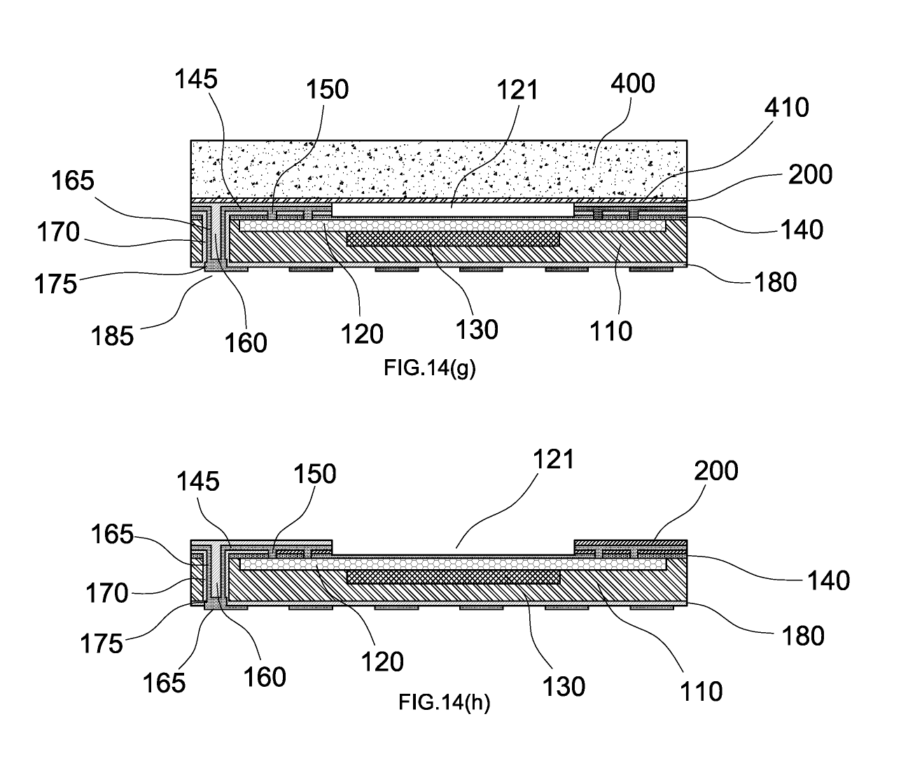

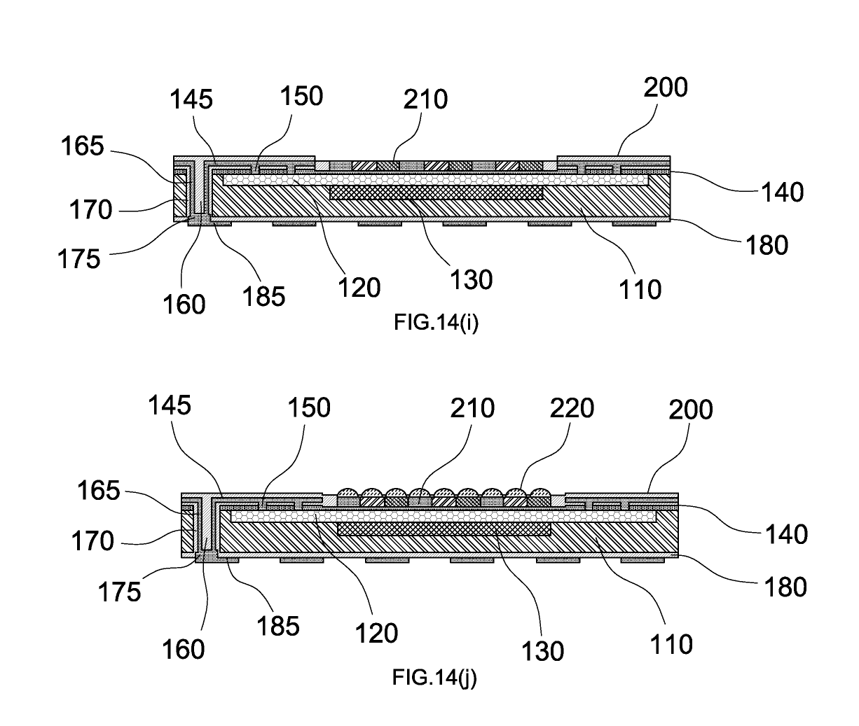

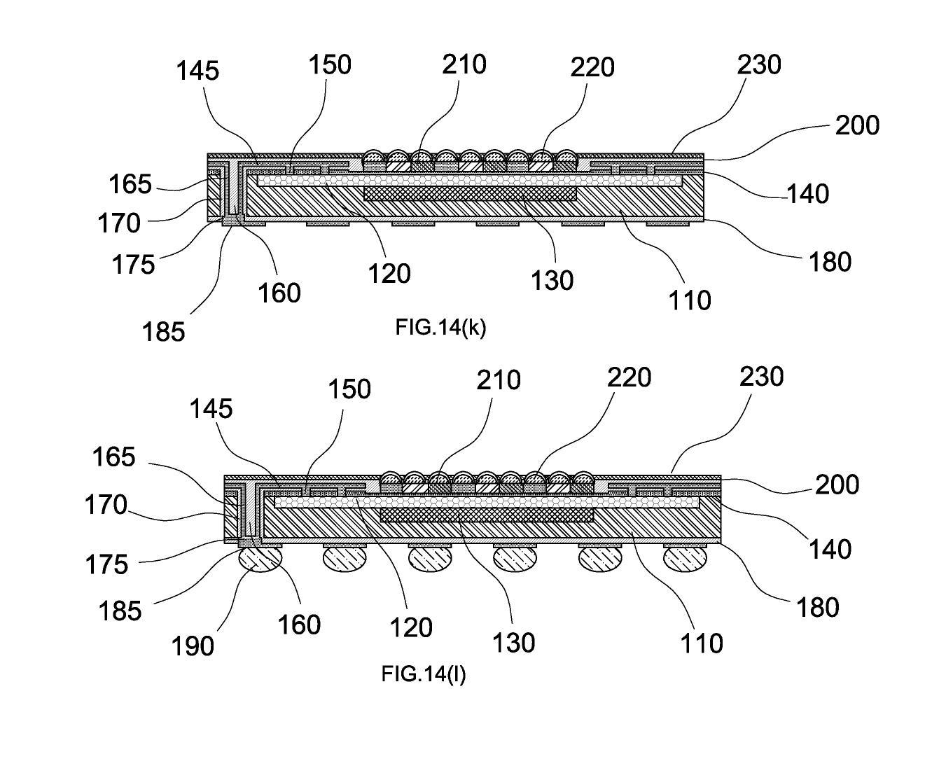

FIGS. 14 (a) to (l) show steps in a preferred method of manufacturing the electronic device package of FIG. 5.

In FIG. 14 (a) a semi-finished package is provided. The semi-finished package comprises a substrate 110 with an optically interactive device 120, 130 positioned on a first surface 110a thereof. The optically interactive device comprises an IC 120 and an optically interactive component 130. An isolation layer 140 covers the upper surface 110a of the substrate 110 and the upper surface of the optically interactive device.

In FIG. 14 (b) a first via hole 160a is formed. The first via hole 160a is preferably formed by a dry etching process (e.g. DRIE—deep reactive ion etching). The first via hole 160a is formed by etching from the first (top) surface 110a of the substrate downwards towards the opposite surface.

In FIG. 14 (c) the first via hole 160a is coated with an isolation layer 170. In addition a dielectric layer 155 (e.g. polymer) is fabricated to cover the isolation layer 140.

In FIG. 14 (d) a metal lining 165 is added on top of the isolation layer 170 of the first via 160. An optical opening or aperture 121 is created by etching away a portion of the dielectric layer 155 which lies above the optically interactive device. Preferably at least part of the isolation layer 140 covering the optically interactive device 120, 130 js etched away also; however this may not be necessary if the isolation layer is transparent to light. Then a redistribution layer 145 is added on top of the remaining isolation layer 140 and dielectric layer 155. The redistribution layer comprises one or more I/O lines that extend over (above) the top surface of the integrated circuit 120.

In FIG. 14 (e) a further dielectric layer 200 (e.g. a polymer) is deposited over the redistribution layer 145. The dielectric layer 200 may be deposited over the whole arrangement and then removed from the optical opening. The dielectric 200 also fills the interior of the first vias 160.

In FIG. 14 (f) a handling wafer 400 is temporarily bonded to the top surface of the assembly by an adhesive 410. The handling wafer 400 supports the assembly and in particular the substrate 110. It allows the assembly to be moved and in particular it allows the substrate 110 to be thinned without snapping. The substrate 110 is thinned, preferably to 150 μm or less, by any appropriate means. For example, a grinding machine may be applied to its bottom surface (the surface remote from the handling wafer).

In FIG. 14 (g) bonding pads 185 are formed on the second (bottom) surface of the substrate 110. Preferably this is done by first depositing a polymer layer 180 for passivation and then sputtering a metal layer. The metal layer is thus patterned to form the bonding pads 185. One or more of the bonding pads 185 may connect to the first via 160 directly or via a connecting portion 175.

In FIG. 14 (h) the handling wafer 400 is removed and the top surface of the assembly is cleaned.

In FIG. 14 (i) a colour filter 210 is fabricated in the optical opening 121 above the IC 120.

In FIG. 14 (j) a plurality of microlenses 220 is fabricated above the colour filter and the IC.

In FIG. 14 (k) a protective polymer film 230 (e.g. parylene) is formed on the top of the assembly and in particular covers the microlenses 220.

In FIG. 14 (l) solder joints 190 are attached to the bonding pads 185. Furthermore, the assembly shown in the figures above is usually part of a mass production process including many similar units fabricated on the same substrate (e.g. silicon wafer) 110. In that case the various units are separated from each other by cutting the substrate 110 at the gaps between them, e.g. by using a die saw.

While the invention has been described above with reference to certain preferred embodiments, this is by way of example only and should not be taken to limit the scope of the invention which is defined by the claims. A person skilled in the art will be aware of and able to carry out certain variations and modifications of the embodiments described above while still remaining within the scope of the claims. In particular while the invention has been described with particular reference to an image sensor package it could be applied to other device packages as well.

1. An electronic device package comprising a substrate having a first surface and a second surface opposite the first surface; an electronic device being positioned on the first surface of the substrate; an isolation layer provided over at least a portion of the top surface of the electronic device; one or more I/O lines connected to the electronic device and extending over the isolation layer and the top surface of the electronic device, and one or more first vias which pass through the substrate and connect said one or more I/O lines to the second surface of the substrate.

2. The electronic device package of claim 1 wherein at least some of said I/O lines extend from one side of the electronic device over the top surface of the electronic device to another side of the electronic device.

3. The electronic device package of claim 2 wherein the I/O lines connect the electronic device to one or more first vias adjacent no more than two sides of the electronic device.

4. The electronic device package of claim 1 wherein the I/O lines connect the electronic device to one or more first vias adjacent no more than two sides of the electronic device.

5. The electronic device package of claim 1 wherein the I/O lines connect the electronic device to one or more first vias adjacent only one side of the electronic device.

6. The electronic device package of claim 1 wherein the electronic device is an image sensor.

7. The electronic device package of claim 1 wherein the electronic device is a MEMs device.

8. The electronic device package of claim 1 wherein the electronic device comprises an integrated chip.

9. The electronic device package of claim 1 wherein the electronic device comprises a mechanical or optically interactive component and an integrated chip for driving the mechanical or optically interactive component.

10. The electronic device package of claim 1 wherein the I/O lines are connected to the electronic device by one or more second vias which extend through said isolation layer.

11. An optically interactive device package comprising an optically sensitive area and a microlens positioned over the optically sensitive area; the microlens being coated with a protective polymer layer.

12. The package of claim 11 wherein the protective polymer layer comprises parylene.

13. The package of claim 11 wherein the protective polymer layer is from 0.05 μm to 5 μm in thickness.

14. The package of claim 11 wherein the optically interactive device is an image sensor.

15. A method of manufacturing an electronic device package comprising:—
a) providing an electronic device on a substrate;
b) providing an isolation layer over at least a portion of a top surface of said electronic device;
c) forming one or more first vias extending through said substrate; and
d) forming one or more I/O lines extending over the isolation layer and the top surface of the electronic device;
said I/O lines connecting the electronic device to the at least one first via.

16. The method of claim 15 wherein the substrate has a first surface and a second surface and the electronic device is provided on a first surface of the substrate and wherein the one or more first vias are formed by drilling or etching from the first surface towards the second surface of the substrate.

17. The method of claim 15 wherein the electronic device is an optically interactive device and comprising the further step of:—
e) placing a microlens over the optically interactive device after step c).

18. The method of claim 16 wherein step e) is performed after steps c) and d).

19. The method of claim 16 wherein the optically interactive device comprises an IC and an optically interactive component; and wherein the one or more first vias are connected to the IC by the one or more I/O lines.

20. The method of claim 14 further comprising the step of forming one or more second vias through the isolation layer to connect the I/O lines to the electronic device.
